(19) United States
(12) Patent Application Publication
(10) Pub. No.: US 2005/0089803 A1
(43) Pub. Date: Apr. 28, 2005

(54) Method of lift-off microstructuring deposition material on a substrate, substrates obtainable by the method, and use thereof

(76) Inventors: Salim Bouaidat, Copenhagen (DK); Jacques Jonsmann, Gorlose (DK); Bjorn Winther-Jensen, Bronshol (DK); Soron Flygenring Christensen, Bradgade (DK)

Correspondence Address: FOLEY HOAG, LLP;PATENT GROUP, WORLD TRADE CENTER WEST, 155 SEAPORT BLVD, BOSTON, MA, 02110, US

(21) Appl. No.: 10/478,947

(22) PCT Filed: Apr. 25, 2002
(86) PCT No.: PCT/DK02/00274

(30) Foreign Application Priority Data
May 23, 2001 (EP) 01610052.1

(51) Int. Cl. G03C 5/00; H01L 21/302

(52) U.S. Cl. 430/312; 430/313; 438/737

(57) ABSTRACT

Methods and apparatus for lift-off microstructuring deposition material, here alternate hydrophilic (601) and hydrophobic (602) letters, on a substrate; a method comprising deposition of polymeric material by plasma polymerisation deposition of monomers of substituted benzenes, (halo)aliphatic compounds, or a combination thereof; another method comprising deposition of polymeric material by plasma polymerisation deposition of monomers of vinyls, substituted vinyls, acrylics, silanes, and phosphites, or a combination thereof; still another method comprising deposition of polymeric material by plasma polymerisation deposition of monomers wherein said plasma is generated by a multiple phase AC supply, or DC supply; and substrates and devices prepared by lift-off microstructuring using plasma polymerisation deposition of monomers according to such methods. Scale A indicates about 100μ.

### BACKGROUND OF THE INVENTION

The present invention relates to methods of lift-off microstructuring deposition material on a substrate; a method comprises deposition of polymeric material by plasma polymerisation deposition of monomers of substituted benzenes and (halo)aliphatic compounds; another method comprises deposition of polymeric material by plasma polymerisation deposition of monomers wherein said plasma is generated by a multiple phase AC supply, or DC supply; and substrates and devices prepared by plasma polymerisation deposition of monomers according to such methods.

1. The Technical Field

In cell-based drug screening, the methods used today are usually tedious and labour consuming. Electrical measurements are typically conducted on single cells under microscope. Here, microelectrodes are positioned on the individual cells manually using micro-manipulators. The cells are then exposed to different drugs, one at a time, and the potential or conductivity etc. is measured. In the case of optical measurements, for instance fluorescence, a cluster of cells producing fluorescent proteins are placed in a flow cell. The drug is introduced to the cluster through a flow system, and the fluorescence they produce is detected using a fluorescence microscope.

In today's High Throughput Screening (HTS), optical screening is usually conducted by steps comprising dispensing cells, using a dispenser robot, into an array of wells on a transparent microtiter plate. Next, a set or sets of drugs, e.g. drugs mixed on-site, is dispensed into the wells, and optical measurements are performed. Detectors are typically placed over the microtiter plate and light sources underneath. One advantages of this technique is the fact that it is highly automated and a number of drugs can be screened simultaneously.

Disadvantages include the fact that larger number of cells and large volumes of drugs (typically from a couple of microliters) are needed in order to do the measurements. Also, the dimensions of the wells limit the number of measuring sites in the array.

Lift-off microstructuring is a technique for providing micro-structured devices, including substrates having microstructured deposition material thereon, said deposition material e.g. being polymeric material or metal. It includes the step of providing a substrate with a sacrificial layer, said sacrificial layer having a predetermined micro-pattern complementary to that of the desirable micro-pattern of the deposition material.

After deposition of the deposition material, the sacrificial layer with deposit thereon is removed, either mechanically or chemically, e.g. by dissolution/etching. In the specific shadow mask lift-off technique, the sacrificial layer constitutes a mask containing said complementary desired pattern. The deposition material is normally deposited in such a manner that it covers the parts of the substrate, which are not covered by the sacrificial layer as well as the parts of the substrate already covered by the sacrificial layer. When the sacrificial layer is removed, e.g. dissolved/etched, a micro-pattern of the deposit material that is complementary to the pattern of the sacrificial layer is revealed.

The term sacrificial layer is intended to cover conventional materials used in micro-patterning deposition of semiconductor devices by lift-off micro-structuring e.g. photo-resists, metals, oxides, ceramics, polymers etc.

There is a need for an improved and more flexible lift-off micro-structuring method and apparatus in which strongly binding deposition materials, including polymers, in particular polymers with different surface properties, can be provided on the same substrate.

2. Prior Art Disclosures

Y. Pan et al., “A Precision Technology For Controlling Protein Adsorption And Cell Adhesion In Biomems”, MEMS'01, “The 14th IEEE International Conference on Micro Electro Mechanical Systems”, pages 435-438, 21-25 Jan. 2001, Interlaken, Switzerland, describe a lift-off process for microstructuring plasma polymerised tetraglyme (pp4G) deposit on a silicon wafer using RF plasma having plasma power densities which to a large extent decomposes ether bonds. The polymerised tetraglyme provides cell non-adhesive surfaces on the surface.

U.S. Pat. No. 4,371,407 discloses a plasma polymerisation method using RF plasma of plasma power densities above 20 W/l for deposition of CF₄, C₂F₆, C₃F₈ in mixture with H₂, i.e. saturated fluorocarbon which requires high plasma power densities for plasma polarisation.

EP 0 741 404 B1 discloses a method and an electrode system for excitation of a plasma.

WO 00/20656 discloses a method of metallizing a surface of a solid substrate.

WO 00/44207 discloses a method of excitation of a plasma by means of a plurality of electrode systems.

C. H. Thomas et al., Transactions of the ASME, Vol. 121, 1999, discloses a process for the preparation of a substrate on which single cells can be isolated on isolated patches of amino-terminated silane surrounded by a non-adhesive hydrogel of acrylamide and polyethyleneglycol.

U.S. Pat. No. 5,470,739 discloses a process for providing a patterned design useful as a cell culture support. Patches of the surface are coated with collagen which influences cell-adhesion.

### 2. DISCLOSURE OF THE INVENTION

Object of the Invention

It is an object of the present invention to seek to provide an improved method and apparatus for microstructuring deposition material on a substrate, in particular lift-off microstructuring.

It is an object of the present invention to seek to provide such a method and apparatus whereby deposition material comprising multiple polymer surfaces can be provided on the same substrate.

It is a further object of the present invention to seek to provide such a method and apparatus which allow a substantial portion of functional groups on monomers for said polymers to be preserved.

Further objects appear from the description elsewhere.

Solution According to the Invention

“Lift-Off Microstructuring—Plasma Polymerisation Deposition of Substituted Benzene and (Halo)Aliphatic Compounds”

In an aspect according to the present invention, these objects are fulfilled by providing a method of lift-off microstructuring a deposition material on a substrate as defined in claim 1, the method comprising:
(a) providing the substrate having a sacrificial layer in a predetermined micro-pattern;
(b) depositing a polymer layer on the sacrificial layer/substrate;
(c) dissolving/etching the underlying sacrificial layer (lift-off),
   characterised in that the polymer layer is constituted by a cross-linked polymeric material prepared by plasma polymerisation of a monomer gas in a plasma, said monomer gas comprising one or more types of monomers selected from
(i) substituted benzenes, and
(ii) (halo)aliphatic compounds of the general formula C_{z}H_{y}Xₓ wherein X is fluoro, 15 chloro, bromo or iodo, z is 1-16 and x+y is 2z+2, 2z, 2z-2 or 2z-4;
   with the proviso that said (halo)aliphatic compounds are not CF₄, C₂F₆, or C₃F₈.

It has surprisingly turned out that for such a micro-structuring method wherein said deposition of a deposition material on said sacrificial layer comprises a plasma polymerisation deposition of a monomer gas, said monomer gas being comprising one or more types of monomers selected from said substituted benzenes, and (halo)aliphatic compounds; with the proviso that said (halo)aliphatic compounds are not CF₄, C₂F₆, or C₃F₈; it is obtained that substrates with microstructured deposition material of low feature sizes, multiple polymer surfaces with accurate alignment, and deposited polymers having functional groups which are sensitive to high plasma power densities can be provided.

Preferred embodiments are defined in the sub claims.

“Monomers—Substituted Benzenes”

In an aspect, lift-off microstructuring comprises plasma polymerisation deposition of a monomer gas comprising one or more types of monomers selected from substituted benzenes.

The substituted benzenes may—as a matter of definition—have 1-6 substituents, but will most often have 1-4 substituents, preferably 2-4 substituents, in particular 2-3 substituents.

It is believed that preferred substituted benzenes are those which have no polymerisable groups such as alkenyl, alkynyl, etc. substituents.

Examples of suitable substituted benzene monomers have the general formula:
Ar(Rⁿ)ₙ
wherein Ar is a benzene ring, n is 1-6 and Rn is n substituents R¹, R², R³, R⁴, R⁵R⁶ covalently bound to the benzene ring, the substituents R¹, R², R³R⁴, R⁵, R⁶ being independently selected from: C₁₋₆-alkyl, C₁₋₆-alkenyl, C₁₋₆-alkynyl, C₁₋₆-alkoxy, C₁₋₆-alkylcarbonyl, C₁₋₆-alkylcarbonyl, C₁₋₆-alkoxycarbonyl, carbamoyl, mono- and di(C₁₋₆-alkyl)-aminocarbonyl, formyl, hydroxy, carboxy, carbamido, thiolo, nitro, cyano, nitro, amino, mono- and di(C₁₋₆-alkyl)amino, and halogen (fluoro, chloro, iodo, bromo), wherein the C₁₋₆-alkyl, C₁₋₆-alkenyl, C₁₋₆-alkynyl and C₁₋₆-alkoxy groups in the above may be substituted with substituents, preferably 1-3 substituents, selected from hydroxy, C₁₋₆-alkoxy, carboxy, amino, mono- and di(C₁₋₆-alkyl)amino and halogen.

In the formula above, it is preferred that the substituents are selected from C₁₋₂-alkyl, amino, and halogen.

Particular examples of suitable substituted benzenes are p-xylene, m-xylene, o-xylene, omethylaniline, m-methylaniline, 2,3-dimethylaniline, 2,4-dimethylaniline, 2,5-dimethylaniline, 2,6-dimethylaniline, 3,5-dimethylaniline, fluorobenzene, etc.

“Examples of further benzene monomers: toluene, xylene, benzaldehyde, chlorobenzene, di-chlorobenzene, trifluorobenzene.”

Particularly useful substituted benzenes are those having two or more substituents where one substituent is a methyl group.

Also preferred are benzenes which do not include alkenyl or alkynyl substituents.

Preferred substituted benzenes are those having at least two substituents.

This being said, it is believed that particularly useful substituted benzenes are those which do not include oxygen atoms. This is particularly true when the substrate is silicon-containing in that any formation of Si—O—C bonds (which may be susceptible to hydrolysis with strong bases) between the oxygen atom of the substituted benzene and silicon atoms of the substrate is thereby avoided. Preferably less than 5 mol-% of the monomers of the substituted benzene type comprises oxygen atoms.

As will be obvious from the above, the monomer gas may comprise other monomer types than the substituted benzene monomers. In order to fully benefit from the advantageous properties provided with the substituted benzene monomers, it is believed that the content of substituted benzene monomers, should be at least 5 mol %, although the content can be even higher such as in the range of 10-100 mol-%, e.g. 25-100 mol-%, such as 75-100 mol-%, and often about 100 mol-%.

The amount defined for the substituted benzenes may encompass one or two or more different substituted benzenes, normally however, only one is used or two are used together.

As mentioned above, it has been found that the double bonds originating from the benzene structure often are virtually absent in the polymeric material prepared from the substituted benzenes. This being said, the materials will generally have less than 20% of the double bonds originating from the benzene structure of the substituted benzenes left. Typically as little as less than 10% of the double bond, preferably less than 5%, of the double bonds originating from the benzene structure of the substituted benzenes are left. This appears to be an important characteristic of the materials of the present invention.

The amount of double bonds left can be determined by FT-IR measurement or by reaction with bromine or fluoro-compounds followed by elemental analysis with EPS (X-ray Photoelektron Spectroscopy).

“Monomers—Substituted (Halo)Aliphatic Compounds”

In another embodiment, said cross-linked polymer may also be provided with a (halo)aliphatic compound of the general formula C_{z}H_{y}Xₓ wherein X is fluoro, chloro, bromo or iodo, z is 1-16. The number of substituents, i.e. the sum x+y, is 2z+2, 2z, 2z-2 or 2z-4 corresponding to straight chain (halo)aliphatic compounds, (halo)cycloaliphatic compound or monounsaturated (halo)aliphatic compounds, and di-unsaturated (halo)aliphatic compounds or mono unsaturated (halo)cycloaliphatic compounds, etc., respectively.

The term “(halo)aliphatic compound” is intended to mean an aliphatic compound 30 optionally being substituted one or more times with fluoro, chloro, bromo or iodo, preferably fluoro or chloro, such as perhalogenated compounds.

Examples of preferred (halo)aliphatic monomers for the process of the invention are:
a) Alkynes: HC≡CH, HC≡C—(CH₂)ᵣ—CH₃ (0≦r≦14).
b) Alkenes: H₂C═CH₂ and H₂C═CH—(CH₂)ᵣ—CH₃ (0≦r≦14) and cyclic alkenes.
c) Alkanes: CH₄, CH3—(CH₂)ᵣ—CH₃ (0≦r≦14) and cyclic alkanes.
d) Haloalipatics: Monomers from group a, b and c containing one or more halogen atoms (F, Cl, Br and I).

The compounds can be utilised either in combination with the substituted benzenes or alone. The (halo)aliphatic compounds provides in themselves hydrophobic surface properties upon plasma polymerisation.

Examples of fully or partially halogenated organic compounds (haloaliphatic compounds) are perfluorocyclohexane, perfluorohexane, perfluoromethylpentene, difluoroethylene, etc.

When the (halo)aliphatic compounds are used, it is believed that the content of (halo)aliphatic monomers should be at least 5 mol-%, although the content can be even higher such as in the range of 10-100 mol-%, e.g. 25-100 mol-%, such as 75-100 mol-%, and often about 100 mol-%. In one embodiment, the (halo)aliphatic compounds are used in combination with the substituted benzenes.

“Other Monomers”

Other types of monomers can be used as the balance in the monomer gas in order to modify the properties of the materials. Such other types of monomer may be provided either by preparing a mixture of monomers to be applied simultaneous or by providing alternating amounts of different monomer types so as to form a virtual mixture in the plasma environment.

Illustrative examples of other monomer types to be selected from vinylacetate, vinylpyrrolidone, ethyleneglycolvinylether, diethyleneglycolvinylether, methyl methacrylate, methyl methacrylate, allylalcohol, vinylbornene, acid anhydrides (in particular carboxylic acid anhydrides), acid halides (in particular carboxylic acid halides) such as acid chlorides, acid bromides, acid fluorides, acid iodides, epoxides, aldehydes, carboxylic acids, and thiols. In addition to the monomers above, the monomer gas may also comprise gaseous monomers such as NH₃, N₂, N₂O, CO₂, etc.

Examples of benzene monomers: toluene, xylene, benzaldehyde, chlorobenzene, di-chlorobenzene, tri-fluorobenzene.

“Lift-Off Microstructuring—Plasma Polymerisation Deposition of Other Monomers—Vinyls, Substituted Vinyls, and Acrylics”

In an aspect according to the present invention, these objects are fulfilled by providing a method of lift-off microstructuring a deposition material on a substrate as defined in claim 13, the method comprising:

A method of lift-off microstructuring of a polymer on a substrate, said method comprising the steps of:
(a) providing the substrate having a sacrificial layer in a predetermined micro-pattern;
(b) depositing a polymer layer on the sacrificial layer/substrate;
(c) dissolving/etching the underlying sacrificial layer (lift-off),
   characterised in that the polymer layer is constituted by a cross-linked polymeric material prepared by plasma polymerisation of a monomer gas in a plasma, said monomer gas comprising one or more types of monomers selected from: vinyls, substituted vinyls, acrylics, silanes, and phosphites, or a combination thereof.

Among monomers, preferred monomers comprises at least one polymerisable group which forms the polymer backbone of the plasma polymerised deposition or coating, and at least one functional group which is preserved during the plasma deposition and which is bound to the polymer backbone.

In traditional liquid phase polymerisation, e.g. free radical polymerisation, the most common polymerisable groups are vinyls, substituted vinyls, and acrylics. Said polymerisable groups are also suited for plasma polymerisation, and polymerise at very low plasma power densities. Low plasma power densities at the same time allow for preservation of the functional group.

Furthermore, plasma technology allows for the use of a large number of polymerisable groups. In fact, nearly any organic compounds may be polymerised in a plasma process. The more inert the group is the higher the required plasma density. However, the higher the plasma power density, the less is the probability that the functional group is preserved. Examples of plasma polymerisable groups which can be polymerised at conveniently low plasma power density are benzenes, silanes, and triphosphites.

In conclusion preferred examples of said polymerisable group P are acrylics, vinyls, benzenes, silanes, and triphosphites.

Examples of acrylic monomers: acrylic acid, methylmethacrylate, acrolein, acryloylchloride, acrylonitrile.

Examples of vinyl monomers: ethylene, propylene, styrene, N-vinylpyrrolidone.

Examples of substituted vinyl monomers: vinyl-di-fluoride, hexafluoropropane, vinylchloride.

“Other Monomers—Silanes and Phosphites”

Examples of silane monomers: tetramethylsilane, hexamethyl-di-silane, tri-methylchlorosilane.

Examples of tri-phosphites: tri-methyl-phosphite, triethyl-phosphite.

“Lift-Off Microstructuring—Plasma Polymerisation Deposition Using Low Plasma Power Density”

In another aspect according to the present invention, these objects are fulfilled by providing a method of lift-off microstructuring a deposition material on a substrate as defined in claim 26, the method comprising:
(a) providing the substrate, the substrate comprising a sacrificial layer thereon, said sacrificial layer having a predetermined micro-pattern;
(b) depositing the deposition material on the substrate and said sacrificial layer; and
(c) dissolving/etching said sacrificial layer,
   wherein said deposition material is polymer constituted by a cross-linked polymeric material prepared by plasma polymerisation of a monomer gas in a plasma, said plasma being generated by a multiple phase AC supply or DC supply.

It has surprisingly turned out that for such a micro-structuring method wherein said deposition of a deposition material on said sacrificial layer comprises a plasma polymerisation deposition of a monomer gas, said monomer gas being comprising one or more types of monomers, selecting a plasma which is provided by a multiple phase AC supply or DC supply ensures a plasma of a level of intensity which allows a substantial portion of the functional groups of the monomer of to be preserved.

Preferred embodiments are defined in the sub claims.

It is particularly advantageous to utilise two-phase or three-phase AC plasma which offers the possibility of using a sufficiently low energy, e.g. energy levels of at the most 15 W/l such as at the most 10 W/l.

In a preferred embodiment, said plasma being generated by a two or three phase AC supply.

In a preferred embodiment, said two or three phase AC supply generates plasma having a plasma power density up to 15 W/l, preferably in the range 0.010 to 10 W/l, in particular 0.010 to 5 W/l.

This type of plasma has a level of plasma power density which allows a substantial portion of the functional groups to be preserved whereby monomers having specific functional group can be used for micro-structuring polymers containing such groups on the substrate.

In a preferred embodiment, said monomer gas comprises one or more types of monomers selected from
(i) substituted benzenes, and
(ii) (halo)aliphatic compounds of the general formula C_{z}H_{y}Xₓ wherein X is fluoro, chloro, bromo or iodo, z is 1-16 and x+y is 2z+2, 2z, 2z-2 or 2z-4.

In another embodiment, said monomer gas comprises one or more types of monomers selected from: vinyls, substituted vinyls, acrylics, silanes, and phosphites, or a combination thereof.

The present invention also provides a substrate prepared according to the process.

“Plasma Polymerisation Deposition”

The plasma type advantageously used in the concept of the present invention is typically one generated by a multiple phase AC supply or a DC supply.

It has been found that this type of plasma has a level of plasma power density which allows a substantial portion of the functional groups to be preserved.

It is particularly advantageous to utilise two or three phase AC plasma which offers the possibility of using a sufficiently low plasma power density, e.g. plasma power density of at the most 15 W/l such as at the most 10 W/l.

Preferably, the plasma power density of the plasma is in the range of 10 mW/1 to 15 W/l, such as 10 W/l to 10 W/l, e.g. 10 mW/1 to 5 W/l.

Other types of generators of the plasma may also be applicable, e.g. RF and MF plasma and pulsed variants thereof, in particular for less energy sensitive functional groups of the monomers.

The pressure in the reaction chamber will normally be in the range of 10-1000 μbar, such as 25-500 μbar.

The pressure in the reaction chamber is controlled by a vacuum pump, and a supply of an inert gas and the monomer gas. The inert gas is suitably a noble gas such as helium, argon, neon, krypton or a mixture thereof.

Hence, a plasma reaction chamber can be adapted in accordance with the instructions given herein with possible modification obvious for the person skilled in the art.

The plasma polymerisation process is normally conducted for a period of 10-1000 s, 20 such as 20-500 s.

The plasma-polymerised material can be provided on the substrate in a substantially uniform thickness if desired. It is believed that the layer thickness of the material generally is in the range of 5-5000 nm, such as in the range of 10-1000 nm, typically 10-200 nm.

“Substrates”

A wide range of substrates are suitable in the method of the invention, thus typically the solid substrate essentially consists of a material selected from polymers, e.g. polyolefins such as polyethylene (PE) and polypropylene (PP), polystyrene (PS), or other thermoplastics such as polytetrafluoroethylene (PTFE), tetrafluoroethylene-hexafluoropropylen copolymers (FEP), polyvinyl-difluoride (PVDF), polyamides (e.g. nylon-6.6 and nylon-11), and polyvinylchloride (PVC), rubbers e.g. silicone rubbers, glass, silicon, paper, carbon fibres, ceramics, metals, etc.

Presently preferred materials are silicon, polyethylene (PE), polystyrene (PS) and glass, of which silicon is particularly interesting in view of the particularly useful products for micro-structuring lift-off techniques.

If the substrate is not supplied with sufficiently clean and ready-to-use surfaces, one or more initial cleaning treatments may be needed. Such cleaning treatments often depend on the substrate and are known in the art.

“Pre-Coated Substrates and Sacrificial Layer”

The substrate (and sacrificial layer) may be pre-coated or pre-treated in order to modify the properties thereof, e.g. the ability of the surface to adhere to the plasma polymerised material, or the hydrophobic or hydrophilic properties of the substrate as such. The pre-coating may (also) be performed by plasma polymerisation. In the case where the substrate is silicon, it is preferred that the surface therefore is pre-treated with a hydrogen plasma before the material is provided onto the silicon in that occasional Si—OH groups are thereby converted to Si—H groups. This step can be performed as a pre-step to the step of providing the polymer layer (see Example 1). Also interesting is pre-treatment with argon so as to clean and possibly activates the surface prior to plasma polymerisation with the substituted benzene.

The surface properties of the polymer is determined by the substituted benzenes and/or (halo)aliphatic compounds used in the plasma polymerisation process, as well as by any additional monomers used as the balance of the monomer gas.

Besides the fact that the polymer in itself may provide specific surface properties, it is also possible to modify the surface properties of the polymer even before the sacrificial layer is dissolved/etched.

As will be understood, hydrophobic, hydrophilic, cell-adhesive and cell non-adhesive surface properties of predefined patches (defined by the micro-pattern) for the substrate may be provided either by mixing suitable monomers with the substituted benzenes or may provided by plasma polymerisation of a further layer on top of the cross-linked material (plasma polymerised monomer gas comprising substituted benzenes).

One advantage of the present process resides in the fact that the plasma-polymerised substituted benzenes provide a durable cross-linked material which has a strong bonding to the substrate (and the sacrificial layer). It is therefore possible to manipulate the substrate and to provide further layers without affecting the integrity of the pattern provided with the cross-linked material (and optional further layers on top thereof).

Thus, the surface properties can be provided by the monomer gas as such; by components provided by plasma polymerisation in succession of plasma polymerisation of the monomer gas; or by “wet” chemical modification of the polymer surface, e.g. initially prepared by plasma polymerisation.

In one important embodiment, the polymer layer is functionalised prior to dissolution (or etching) of the underlying sacrificial layer.

The monomer gas as such can provide either a hydrophobic surface, i.e. when substituted benzenes with substituents other than amino, mono- and di(C₁₋₆-alkyl)amino, thiolo and hydroxyl are used and when the (halo)aliphatic compounds are used, or a hydrophilic surface, i.e. when substituted benzenes with amino, mono- and di(C₁₋₆-alkyl)amino, thiolo and hydroxyl substituents are used.

As it is illustrated in the examples, a further plasma polymerised layer may be provided on top of the material defined above. Such a layer may provide modify the surface properties of the polymer and may provide special surface properties to the material, e.g. hydrophobicity, hydrophilicity, cell-adhesive surface property, cell-repellence properties, etc.

The further plasma polymerised layer may be provided in direct succession of the polymer layer, i.e. as in illustrated in Example 2 where the monomer gas containing the substituted benzene is turned off after which the 1-vinyl-2-pyrolidone monomer is provided. This direct succession of monomers provides a very strong bonding between the two layers.

Alternatively, the further plasma polymerised layer may be provided in a separate process.

In the process of preparing the cross-linked materials it is possible to add a monomer which provides hydrophilic properties either simultaneously with plasma polymerisation of substituted benzene or subsequent to plasma polymerisation of substituted benzene (see Example 2). Examples of monomers which can be combined with substituted benzenes or which can be polymerised in a subsequent step are acrylic acid, vinylacetate, ethanol, ethylenediamine, allylamine, vinylpyrolidone, vinylaniline, imidazoles such as vinylimidazole, or a mixture of acetylene and N₂O, etc.

When used herein, the term “cell non-adhesive surface” is intended to refer to a non-adhesive surfaces with regards to cells, i.e. a surface which prevents bio-fouling.

Examples of monomers which in combination with substituted benzenes or in a subsequent step provides a cell non-adhesive surface are polyethyleneglycols and derivatives, e.g. triethyleneglycol (“triglym”) and diethylene-glycol-vinylether (DEGVE), as well as silicone monomers, e.g. hexamethylcyclotrisiloxane (D3).

When used herein, the term “cell-adhesive surface” is intended to refer to a surface with predominant adhesion to cells, i.e. a surface which promotes cell-attachment.

Examples of monomers which provides a cell-adhesive surface area are acid and/or base groups, e.g. acrylic acid and allylamine, vinyldifluoride, and the like.

Thus in one embodiment, the invention provides a substrate with a hydrophilic surface.

In another embodiment, the invention provides a substrate with a hydrophobic surface.

In a further embodiment, the invention provides a substrate with a cell-adhesive surface.

In a still further embodiment, the invention provides a substrate with a cell non-adhesive surface.

In an even still further embodiment, the invention provides a substrate with a surface which is either:
hydrophilic and cell-adhesive,
hydrophilic and cell non-adhesive,
hydrophobic and cell-adhesive, or
hydrophobic and cell non-adhesive.

Thus, the substrate may have a surface which has more than one functionality. This makes it possible to accurately design the surface to, e.g., discriminate between various types of cells.

The various surface properties can also be provided by “wet” chemical process. As an example, conducting surfaces may be provided in a subsequent step, i.e. after polymerisation of the substituted benzene (and other monomers), by means of combinations of monomers and constituents already known in the art, e.g. electro30 polymerisation of pyrrole (see, e.g., “Preparation and Characterisation of Processable Electroactive Materials, Anders Ravn Sorensen, Ph.D. Thesis, July 1993, ATV

Erhvervsforskerprojekt EP 336, Denmark) and sputtering of metals, e.g. platinum, in thin (1-100 nm) layers, and subsequent electrochemical method for the preparation of thick (0.5-10 μm) metal layers, e.g. copper layers.

Furthermore, “wet” chemical modification of the surface of the plasma polymerised polymer may also involve reaction with any functional groups of the polymer, e.g. amino groups, etc. so as to attach entities with specific affinity for biomolecules, e.g. proteins, cells, DNA, RNA, PNA, LNA, etc.

“Medical Devices and Bio-Devices”

In another aspect according to the present invention, these objects are fulfilled by providing medical devices or bio-devices on which a plurality of patches or areas is provided by lift-off microstructuring according to the present invention.

In a preferred embodiment, a device comprising a micropatterned structure, said device comprising a substrate and a plurality of patches and/or areas comprising a cross-linked material prepared by plasma polymerisation deposition of a monomer gas in a plasma, said monomer gas comprising one or more types of monomers, preferably said type of plasma having a sufficient low plasma power density, said monomer being selected from
(i) substituted benzenes, and
   (ii) (halo)aliphatic compounds of the general formula C_{z}H_{y}Xₓ wherein X is fluoro, 15 chloro, bromo or iodo, z is 1-16 and x+y is 2z+2, 2z, 2z-2 or 2z-4.

In one embodiment, the process steps are repeated two, three or more times whereby patches having different surface properties can be provided on the same substrate.

In particular, this makes it possible to provide a device, wherein the plurality of patches comprising the cross-linked material represents any of the following combinations of surface properties:
(i) a subset of the patches and/or areas having a cell non-adhesive surface and a subset of the patches and/or areas having a cell-adhesive surface;
(ii) a subset of the patches and/or areas having a cell-adhesive surface and a subset of the patches and/or areas having a hydrophobic surface;
(iii) a subset of the patches and/or areas having a cell non-adhesive surface and a subset of the patches and/or areas having a hydrophobic surface;
(iv) a subset of the patches and/or areas having a cell-adhesive surface and a subset of the patches and/or areas having a hydrophilic surface; or
(v) a subset of the patches and/or areas having a cell non-adhesive surface and a subset of the patches and/or areas having a hydrophilic surface.
   “Industrial Uses”

The material has proven particularly useful for providing tough cross-linked layers for the present micropatterning processes where the lift-off technique is utilised. The lift-off technique requires that the materials used can resist treatment with strong solvents such as acetone, toluene, dichloroethylene, THF, etc. or strong alkaline conditions such as NaOH solutions at pH 14, etc. As will be evident from Example 4, the cross-linked materials provided with the plasma polymerisation of substituted benzenes are extremely useful for lift-off processes.

Some important applications of the invention are believed to be diagnostics or drug discovery. These applications often require some sort of manipulation, immobilisation or positioning of biological entities such as cells, or liquids such as regents and drugs.

In cell-based screening, it is very desirable to be able to automatically position cells in an array and apply different test liquids to the cells—possibly fully integrated in a bio microchip.

Two possible schemes include: firstly, an array with small cell-adhesive surface patches, typically below 5 μm in diameter, where the cells are attached. The cell-adhesive surface patches are surrounded by a cell non-adhesive surface area, which prevents cell-attachment. Cells usually have high affinity to almost all surfaces. By deposition a polymer with suitable surface properties, for instance polyethylene glycol (PEG) or plasma-polymerised tetraglyme (pp4G), this can be prevented effectively (Y. Pan et al., 435-438, MEMS'2001).

Secondly, in a more elaborate scheme, test liquids are positioned on top of the cells. Small cell-adhesive surface patches are surrounded by small hydrophilic patches, which in turn are surrounded by a hydrophobic area. The liquids are applied onto the hydrophilic area using a standard micro dispenser. The surrounding highly hydrophobic area constrains the liquids and cells to the small measuring sites. Separate measurements, either electrical or optical can then be conducted. Fluorescence measurement is an especially interesting application, since it is widely used in cell-screening. Detectors could be placed over the measuring sites and a light source underneath. This however requires a transparent substrate such as glass instead of silicon.

In the case of electrical measurements, different electrodes, for instance AgCl, Au, Pt, etc. and different electrode configurations may be used. Electrodes can be located at each measuring point or wherever on the substrate.

Thus, the present invention has the potential of making especially the tedious electrical measurement methods obsolete, since it is a more or less fully automated array, which can screen a large number of drugs simultaneously. The main advantages of the present invention compared to optical HTS is, that single cell measurements are possible and that much smaller drug volumes (nanoliter range) are needed. Also, since the area of each measuring point is much smaller than that of the conventional HTS, a much bigger array per area is possible. The measurement procedure is very similar to the one described further above. It could be as follows: Cell suspension is dispensed over the measuring points in the array using a micro-dispenser. The small cell-adhesive surface patches fixate single cells. The rest of the cells are sucked away through holes in the substrate or by flushing the surface. Next, a set or sets of drugs are dispensed over the measuring points and the measurement is conducted. When the measurement is finished, the drugs are removed and a set of new drugs may be dispensed and new measurements are performed.

Particular applications which can be envisaged for the products of the present invention are:

1. Conducting circuits for micro sensors, in particular for environments of harsh chemical exposure.

a. Micro sensors for the chemical industry, organic synthesis and analytical purposes, e.g. pH measurements, measurement of ionic strength, and measurement of salt concentrations.

b. Micro sensors for biotechnological purposes, including sensors for implantation in living organisms (such as humans), e.g. sensors for measurement of blood sugar in diabetic patients, sensors for measurement/registration of nerve pulses (e.g. in muscles, skin, brain, spinal marrow) and sensors for measurement of conductivity in micro flow systems.

2. Conducting circuits for micro actuators, in particular for environments of harsh chemical exposure, and for biotechnological purposes including sensors for implantation in living organisms (such as humans).

a. Actuators for stimulation of nerves in living organisms e.g. in muscles, skin, brain, spinal marrow.

b. Actuators for controlling mechanical units, e.g. dosage pumps, in living organisms and in micro flow systems.

3. Conducting structures for establishing voltage fields which render it possible to control movement and/or fixation of, e.g., biomolecules such as cells and proteins by utilising the inherent charge of such molecules in combination with the applied voltage in the conducting structure.

a. Conducting structures for micro electrophoresis b. Conducting structures for movement and fixation of cells and other biomolecules in micro flow systems.

4. Conducting circuits for electronic components.

5. Optically active/non-optically active structures or structures where various parts have different optical properties.

Designations and Expressions

In the present context, it is intended that the expression “microstructuring” has a similar meaning as the term “micropatterning”.

The expression for various frequencies of a plasma have the following meanings: DC: 0 Hz, AC: 1 Hz to 10 kHz, RF: 13.45 MHz, and MF: about 2.6 GHz.

Generally, the expression “hydrophobic” covers surface properties exhibiting a contact angle of 90 degrees or above. In the present context, however, the expression “hydrophilic” is ascribed to surfaces having contact angles less than 30 degrees which surfaces ensure wetting thereof. The expression “hydrophobic” is here ascribed to surfaces having contact angles larger than 60 degrees. Other definitions are defined elsewhere in the description.

### 3. BRIEF DESCRIPTION OF THE DRAWINGS

In the following, by way of examples only, the invention is further disclosed with detailed description of preferred embodiments. Reference is made to the drawings in which

FIG. 1 shows an embodiment of lift-off microstructured plasma polymerised polymers on a substrate according to the invention;

FIG. 2 shows another embodiment of lift-off microstructured plasma polymerised polymers on a substrate according to the invention;

FIGS. 3A-3D show a preferred embodiment of a method of microstructuring a deposition material on a substrate by a shadow lift-off microstructuring;

FIGS. 4A-4F show a preferred embodiment of a method of lift-off microstructuring a deposition material on a substrate by the lift-off method;

FIGS. 5A-5H show a preferred embodiment of a method of lift-off microstructuring a deposition material a substrate using a metal sacrificial layer, plasma polymerisation deposition, and lift-off according to the present invention;

FIG. 6 shows a Scanning Electron Microscope (SEM) image of a microstructured silicon-oxide surface having a microstructure pattern in form of capital letters provided by plasma polymerisation deposition according to the present invention;

FIG. 7a shows a cross-sectional top-view illustration of an electrode arrangement in a plasma deposition apparatus according to an embodiment of the present invention;

FIG. 7b shows a cross-sectional top-view illustration of another electrode arrangement in a plasma deposition apparatus as shown in FIG. 7a; and

FIGS. 8-11 show CCD-camera images (10× magnification) of bacterial sedimentation test slides having cell adhesive, cell non-adhesive, hydrophilic, or hydrophobic surfaces.

### 4. DETAILED DESCRIPTION

“Microstructured Devices”

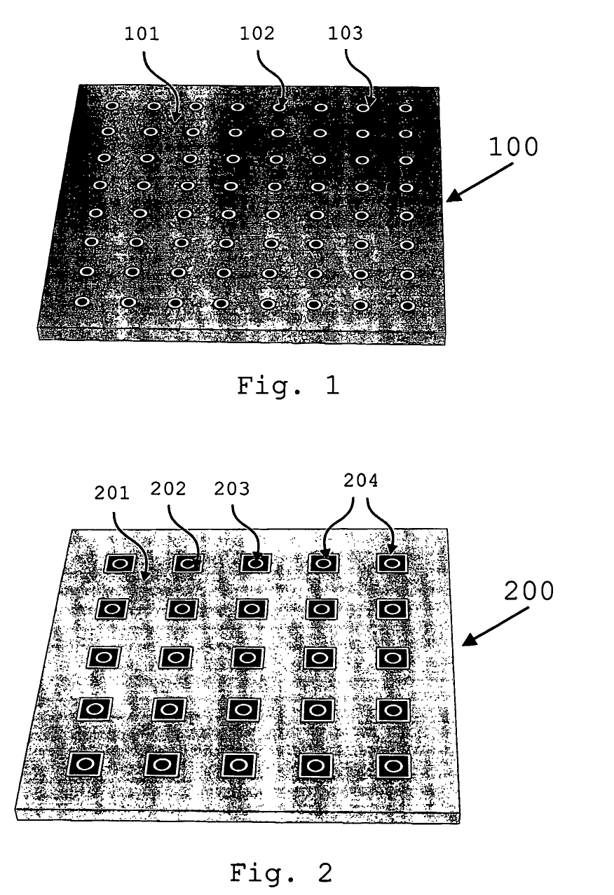

FIG. 1 shows an embodiment of lift-off microstructured plasma polymerised polymers on a substrate according to the invention.

Surfaces of a lift-off microstructured plasma polymerised polymer on a substrate silicon chip comprises an 8×8 array of patches of cell-adhesive surface 102 and cell non-adhesive surface 101 there between.

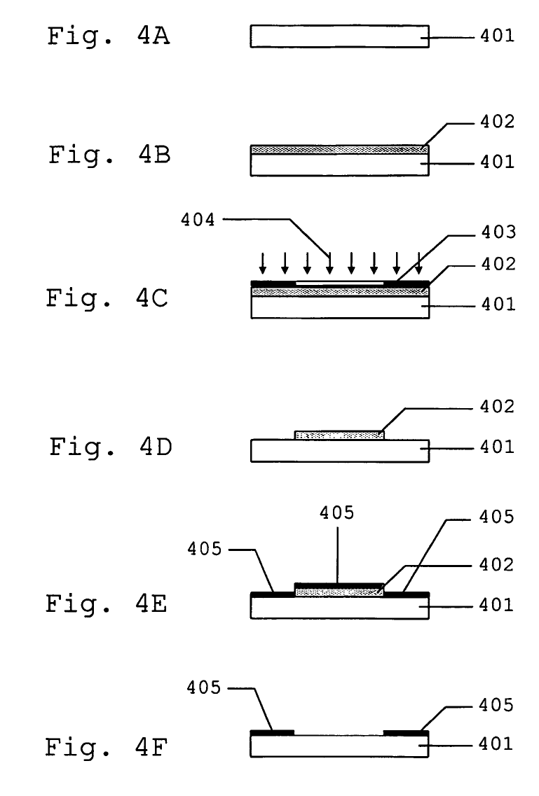

Surfaces of a substrate, here in form of a silicon chip 100, is microstructured by a lift-off microstructuring method according to the present invention, said method comprising plasma polymerisation deposition of a base coating prepared by plasma polymerisation deposition of para-xylene as described in example 1 followed by deposition of a top coating prepared by plasma polymerisation of allylamine forming patches 102 of cell-adhesive surfaces. The plasma is prepared as described in example 10 according to the procedure illustrated in FIGS. 4A-4F, repeated twice with alignment there between. The white edges 103 illustrate non-covered substrate.

The non-adhesive surface 101 is prepared by deposition of a base coating prepared by plasma polymerisation deposition of para-xylene as described in example 1 followed by deposition of a tetra-methylsilane/tri-methylphosphite/Ar-plasma as described in example 10 and microstructured by repeated use of the lift-off microstructuring method.

Single cells can become affixed and/or positioned to cell-adhesive surfaces but not to the non-adhesive surfaces that surrounds the patches, or at least cannot be effectively bound thereto.

FIG. 2 shows another embodiment of lift-off microstructured plasma polymerised polymers substrate in form of chip 200 according to the invention, similar to that shown in FIG. 1 but further including patches 202 of hydrophilic cell non-adhesive surface surrounding the hydrophilic cell adhesive surfaces 203. The hydrophilic cell non-adhesive patches are surrounded by a hydrophobic matrix 201. The white edges 203 illustrate non-covered substrate.

The hydrophilic cell adhesive surfaces and the hydrophilic cell non-adhesive patches are prepared by plasma deposition as described for FIG. 1. The hydrophobic surface is prepared by plasma deposition of para-xylene as described in example 1. The microstructuring is carried out according to the procedure illustrated in FIG. 4. The micro-structured silicon chip 200 comprises a 5×5 array of a hydrophilic cell-adhesive surface 203 surrounded by a hydrophilic cell non-adhesive area 202 and a hydrophobic surface 201 there between.

“Microstructuring by Shadow Mask Lift-Off Technique”

In a preferred aspect, microstructuring by lithographic fabrication is based on the shadow mask lift-off technique, said method being improved according to the present invention.

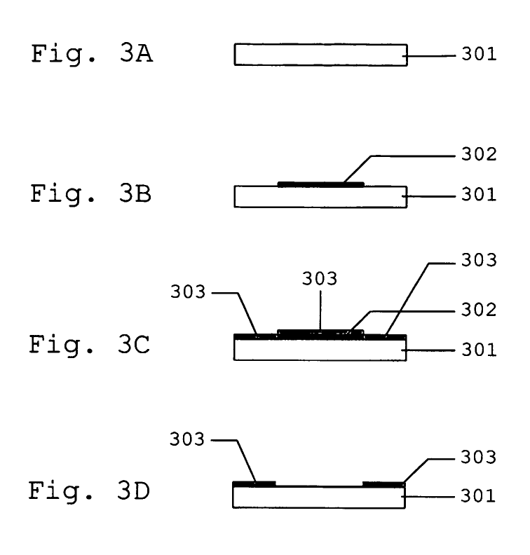

FIG. 3 shows a preferred embodiment of microstructuring of a deposition material on a substrate by a shadow mask lift-off method, said method comprising the steps of providing a sacrificial layer, said layer having a complementary pattern of that desired in the microstructured deposit material on the substrate, deposition of the deposition material on the substrate cover by said sacrificial layer wherein said deposition of deposition material comprises a step of plasma polymerisation deposition according to the present invention.

FIG. 3B shows a sacrificial layer, here a so-called shadow mask 302, e.g. in form of a patterned metal film or a cello tape, placed directly on a substrate 301 (FIG. 3A).

FIG. 3C shows deposition of a deposition material 303, here a polymer deposited by plasma polymerisation deposition according to an embodiment of the present invention, on said sacrificial layer 302 and substrate 301.

Finally, as shown in FIG. 3D, the sacrificial layer 302 with deposited deposition material 303 is dissolved/etched, lifting off undesired parts of the deposit material and providing a desired microstructure pattern of deposited material, here a plasma polymerisation deposition material, on the substrate.

With this technique lower feature size of about 20 μm can be achieved. Although for practical purposes the lower feature size is closer to 50 μm.

An advantage of this shadow mask lift-off technique is that it is very simple, the sacrificial layer being a prepared shadow-mask positioned directly on the substrate to have a microstructuring deposit material deposited thereon.

Further, application of multiple layers of deposit materials can be achieved by successively repeating the method on the same substrate.

A disadvantage of this shadow mask lift-off technique is that it is difficult to obtain multiple layers for small feature sizes because accurate alignment of the shadow mask is difficult, or even impossible, for lower feature sizes, e.g. in the range 1-2 μm.

“Microstructuring by Lift-Off Technique”

In a preferred aspect, microstructuring by micro-lithographic fabrication is based on the well-known lift-off technique, employing conventional deposition techniques, see, e.g. S. M. Sze, Semiconductor Devices, Physics and Technology, John Wiley & Sons, 1985, pp. 441-442, said method being further improved according to the present invention.

FIGS. 4A-4F show a preferred embodiment of microstructuring a deposition material on a substrate by the lift-off method, said method comprising: a step of providing a sacrificial material, here a layer of photoresist, on a substrate, said sacrificial layer comprising a complementary pattern of the final microstructured deposited material; a step of depositing a deposition material on said deposited sacrificial layer and substrate, and a step of lifting off said sacrificial layer covered with deposited material, said lift-off process leaving deposited material on the substrate; wherein said step of depositing a deposition material comprises a step of plasma polymerisation deposition of a microstructuring deposition material according to the present invention.

FIG. 4B shows a sacrificial layer in form of a thin UV-sensitive photoresist 402, here a negative resist typically having a thickness in the range 1.5-4.2 μm spun onto a substrate 401 (FIG. 4A), here a standard silicon wafer. After a short bake, typically at a temperature of 90° C. for 30 s on a hotplate (the baking time being adapted to the resist thickness), the photoresist 402 is lithographic exposed to UV-light 404 through a mask 403. The pattern of the mask is thereby transferred to the photoresist as shown in FIG. 4C. The unexposed photoresist is dissolved/etched in a negative resist process by a resist developer, typically a NaOH solution as shown in FIG. 4D, providing a sacrificial layer with a complementary pattern of the microstructure to be deposited on the substrate. FIG. 4E shows deposition of a deposit material 405 on the developed photoresist 402 and substrate 401, here deposition by plasma polymerisation deposition according to an embodiment of the present invention, as described further and exemplified below.

Finally, as shown in FIG. 4F, the underlying photoresist sacrificial layer 402 with deposited material 405 is dissolved/etched thereby “lifting off” the undesired deposited material, here plasma deposited polymer, providing the desired microstructure pattern of deposited material, here a plasma polymerisation deposit.

This chemical lift-off is preferably performed using acetone in an ultrasonic bath.

For application of multiple microstructuring polymer layers, the process sequence is simply repeated after precise alignment using dedicated microlithography equipment.

“Lift-Off Microstructuring Using Metal Sacrificial Layer”

In a preferred embodiment of the present invention, the sacrificial layer is a metal layer.

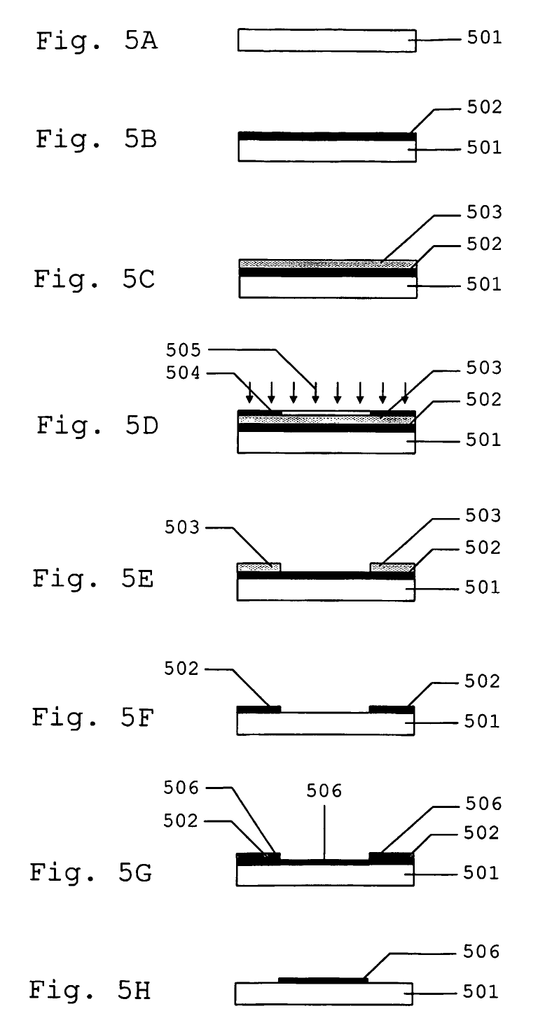

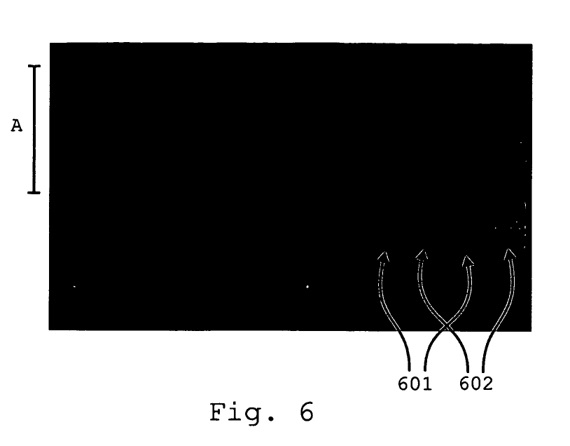

FIG. 5A-5H show a preferred embodiment of a method of lift-off microstructuring a deposition material on a substrate using a metal sacrificial layer, plasma polymerisation deposition, and lift-off according to the present invention.

FIGS. 5A-5B show a metal 502 (FIG. 5B), e.g. aluminium, deposited on a substrate 501 (FIG. 5A), e.g. a silicon wafer, by electron-beam evaporation or sputtering.

FIG. 5C shows a thin UV-sensitive photoresist 503 spun onto the metal deposit 502 on the substrate. After a short bake, the resist is exposed, here by UV light 505, through a mask 504, see FIG. 5D.

FIGS. 5E-5F show the step of development (FIG. 5E) of the photoresist 503 and etching off metal sacrificial layer 502 providing a complementary pattern (negative) in the metal sacrificial layer; see FIG. 5F. In FIG. 5G, a plasma polymerisation deposition layer 506, here a polymer, is applied to the patterned metal sacrificial layer.

In FIG. 5H the metal layer 502 with polymer deposit 506 thereon is lifted off from the substrate 501.

The photoresist is dissolved in acetone.

Preferable etching agents for aluminium include:
(a) phosphoric acid, preferably in a ratio H₂O:H₃PO₄:HNO₃ of 2:16:1 at 50° C.;
(b) acidic acid, preferably in a ratio H₂O:H₃PO₄:HNO₃:CH₃COOH of 5:76:3:15 at 40° C., or
(c) NaOH.

The steps of plasma polymerisation deposition and development shown in FIGS. 5G and 5H are equivalent to the steps shown in FIGS. 4E-4F in the lift-off process.

FIG. 6 shows a Scanning Electron Microscope (SEM) image of a silicon-oxide surface having a microstructure pattern in form of capital letters provided by plasma polymerisation deposition according to the present invention.

Plasma polymerised polymers were deposited on the surface of a substrate. The letters are “written” with alternate hydrophilic 601 and hydrophobic 602 letters. The letters have a height of approximately 35 μm and a width of 25 μm; the scale A indicates about 100 μm. The hydrophilic surfaces were prepared by plasma deposition of N-vinylpyrrolidone, and the hydrophobic surfaces were prepared by plasma deposition of para-xylene.

“Lift-Off Microstructuring Apparatus”

Apparatus for carrying out lift-off microstructuring of a deposition material on a substrate according to the present invention comprises a plasma polymerisation deposition apparatus which deposition apparatus is adapted to provide a plasma polymerisation gas of a suitable plasma power density to preserve a substantial portion of the functional groups of the monomer gas used in said plasma polymerisation.

In a preferred embodiment, the plasma polymerisation deposition apparatus comprises an electrode system providing an AC, or virtual DC plasma, in a reaction chamber containing a sample holder for a substrate to be treated.

Such an electrode system is disclosed in EP 0 741 404, the content of which is incorporated by reference. Generally, this electrode system comprises a number of electrodes connected to various AC voltages of different voltages, frequencies, and each voltage having voltage phase shifts with respect to each other. The voltages are in the range 50-10.000 volt, preferably 100-2000 volt. The frequencies are in the range 10 to 10.000 Hz, preferably 30 to 200 Hz, in particular 50 or 60 Hz. In cases where 3 or more phases are used the phase shifts are selected so that the plasma intensity is substantially constant during the various cycles of the voltages for the number of voltages applied. E.g. for n voltages a phase shift of 1/n period is preferred, i.e. for n=3 a phase shift of 360/3 degrees is preferred.

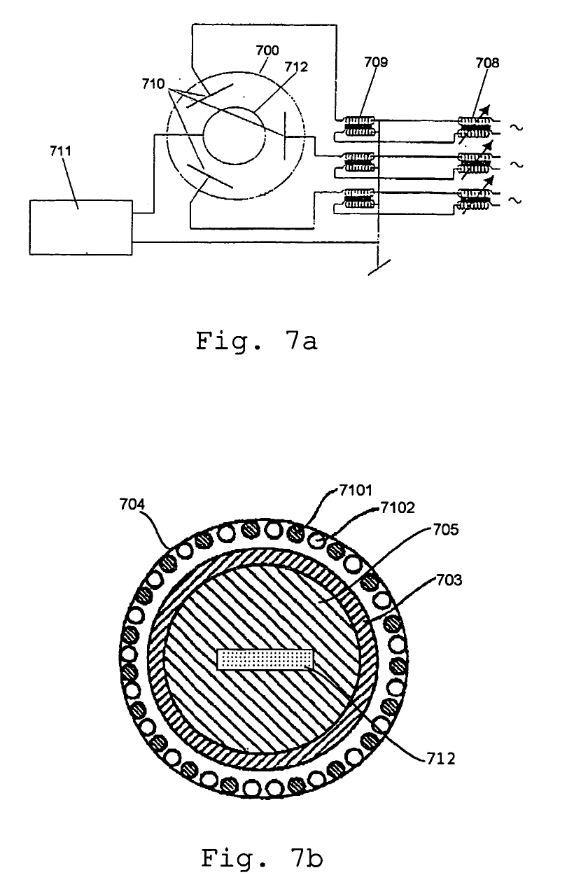

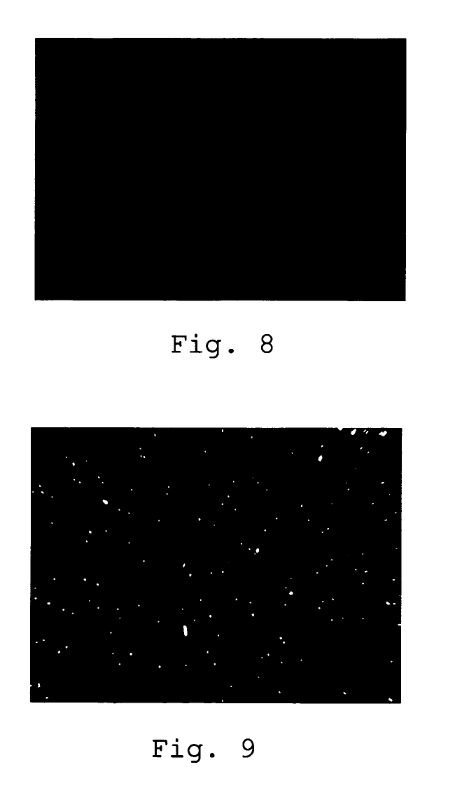

FIG. 7a shows a cross-sectional illustration of an electrode arrangement in a plasma deposition apparatus according to an embodiment of the present invention.

Three electrodes 710 are arranged in a vacuum chamber 700 to provide plasma in a reaction section thereof for exposure of a substrate to said plasma. The electrodes are connected to three voltages 709, here three step-up AC transformers, e.g. CAMP.02533 supplied by Nordelet Tronica, Italy, and further connected to three variable AC transformers 708. The transformers can be of any suitable kind e.g. Vario RV31002-20 3x10A 0-220V supplied by Lubcke. The reaction section comprises a substrate holder 712 which in a preferred embodiment is supplied with a DC voltage. During the pre-treatment step the ion bombardment of the substrate can be amplified by applying a negative voltage bias to the substrate holder. During the top coating deposition the ion bombardment of the substrate can be reduced by applying a positive voltage bias on the substrate holder. The substrate holder can be arranged in any suitable way (not shown) which ensures a sufficiently homogeneous plasma along the surface of the substrate.

The vacuum chamber comprises various inlets and outlets (not shown) for supplying gasses to and from the vacuum chamber, e.g. inlets for process gases such as Ar and H₂, and monomer gasses for plasma polymerisation deposition according to the invention, and outlets connected to one ore more vacuum pumps for discharge of waste gasses and for sustaining vacuum.

FIG. 7b shows a cross-sectional illustration of another electrode arrangement in a plasma deposition apparatus as shown in FIG. 7a.

Such an electrode system is disclosed in WO 00/44207, the content of which is incorporated by reference. Generally, this electrode system comprises a number of electrodes arranged along an inner surface 704, here a glass cylinder, of the vacuum chamber so that phase-shifted voltages supply pairs of electrodes 7101, 7102. The electrode generates an inhomogeneous plasma zone 705 and an inner (central) zone of homogeneous diffusion plasma. A substrate holder 712 for carrying a substrate is arranged in the plasma diffusion zone.

2-phase voltages instead of the 3-phase voltage supply shown in FIG. 7a supply the electrodes.

The vacuum chamber comprises various inlets and outlets (not shown) for supplying gasses to and from the vacuum chamber similar to those described for the embodiment shown in FIG. 7a.

“The Plasma Power Density”

The reactions going on in the plasma strongly depend on the average plasma power density, ρₚₗₐₛₘₐ which is conveniently defined as the ratio of the electrical power over the total plasma gas volume, Vₚₗₐₛₘₐ,
ρₚₗₐₛₘₐ=electrical power/Vₚₗₐₛₘₐ (1)
where the electrical power is given by the product of the measured voltage over the electrodes multiplied by the measured current of the power supply output, and where the gas plasma volume is given by the volume of the plasma section. Depending on the electrode set-up it can be difficult to determine the exact boundary of the plasma volume and thereby the total plasma volume. As a rule of thumb the gas inside the plasma volume emits visible light, thus the position of the plasma volume boundaries can be estimated by observing the plasma from various angles. However, this is not always practically achievable. In the case of AC diffusion plasma the total plasma volume to a good approximation is given by the volume encompassed by the outermost electrodes. E.g., for a cylindrical electrode set-up of radius R and length H, the total plasma volume, Vₚₗₐₛₘₐ, is given by
Vₚₗₐₛₘₐ=H×π×R² (2)

In the following this definition of total plasma volume is used to calculate average plasma densities in accordance with equation (1).

The average plasma power density, ρₚₗₐₛₘₐ, can be accurately controlled by varying the following plasma process parameters: Electrode voltage, pressure, and gas composition. Within a certain process window 200 ρₚₗₐₛₘₐ increases with increasing electrode voltage and increases with increasing pressure. The dependence of ρₚₗₐₛₘₐ on the gas composition is quite complex. However, the presence of easily ionised and otherwise inert gasses such as the noble gasses ensures the existence of plasma even at low average power densities such preferred in the present invention. For typical feed gas compositions the process window is defined by electrode AC voltages in the range 200-2000 V and pressures in the range 0.01-1 mbar.

For a number of popular electrode geometries approximate values of Vₚₗₐₛₘₐ can be calculated in accordance to equation (1) by inserting proper values of H and R. For an inductively coupled plasma with a cylindrical coil wound around a cylindrical vacuum container, H is given by the length of the coil and R is given by the inner radius of vacuum container. For a plasma sustained between two parallel circular electrodes, H is the distance between the electrodes, and R is the radius of the electrodes.

It should be noted that values for the plasma power density for any given plasma section, which geometrical form may deviate from that of the cylindrical electrode set-up in equation (2), can be calibrated against such a standard plasma section. This can be achieved by optical emission spectroscopy (OES) measurements of the emitted light from the plasma, since the intensity of the emitted light is quite sensitive to the plasma power density. For the purpose of calibration pure noble gas plasma is preferred. For any such noble gas a large number of emission wave lengths are present in the emitted light. However for each noble gas, the intensity of certain wavelengths are dominating and therefore especially useful for performing such a calibration, e.g. in the case of a pure argon plasma the intensity of the optical emission at 434.8 nm is relatively intense, and for a pure helium plasma the emission at 587.6 nm is strong.

### 5. EXAMPLES

Preferred embodiments of the invention are further illustrated by the following examples.

### Example 1

### “Lift-Off Microstructuring on Silicon Wafers-Base Coating by Plasma Polymerisation Deposition of p-xylene—Hydrophobic Functionality”

The lift-off microstructuring method steps were conducted as illustrated in FIGS. 4A-4F under the following conditions.

Precise alignment between two or more plasma polymerised polymer surfaces is achieved using lithography equipment and alignment marks formed on the silicon substrate; said equipment being known in the art.

Except for step E, shown in FIG. 4E, the method is conducted following conventional methodologies, see e.g. “Lithography in Experimental Environment” by Hovinen, Malinin and Lipsanen, Helsinki University of Technology, in Reports in Electron Physics 2000/21, Espoo 2000).

Step A: “Substrate”

Silicon substrates, here standard 4″ silicon wafers (Okmetic Oy) on which SiO₂ is grown, were provided.

SiO₂ Growth:

Equipment: Tempress system
Process: Wet oxidation
Temperature: 1000° C.
Pressure (H₂O): 760 Torr
Time: 10 min
Oxide film thickness: 1000 Å
   Step B: “Sacrificial Layer—Photoresist Layer”

A resist was spun on said substrate.
Equipment: SSI 150 dual track spinner
Resist: AZ5214E (Shipley Company, L.L.C)
Thickness: 4.2 μm
Dispensed volume: approx. 4 ml
   Spin:
Speed: 700 rpm
Time: 40 s
   Rest:
Time: 150 s
   Bake (Hotplate):
Temperature: 90° C.
Time: 120 s.
   Step C: “Lithography”
   Exposure of Photoresist
Equipment: Karl Suss MA/BA6 aligner
Process: Positive resist
   Settings:
Mode: Soft contact
Alignment gap: 20 μm (Gap between the resist and mask during alignment for alignment between to polymer surfaces)
Exposure gap: 0 μm (soft contact between mask and resist during exposure)
Exposure time: 16 s
Lamp power: 300 W
Wavelength: 365 nm

The mask was a conventional mask prepared according to the principles disclosed by S. M. Sze, “Semiconductor Sensors”, John Wiley & Sons, 1994, 1^{st} edition, pp. 25-27, here by computer-generated quartz mask photolithography.

Step D: “Development of Resist”

Developer: AZ 351B (Shipley Company, L.L.C) Dilution
ratio to water: 1:5 (Developer: basic NaOH at pH 14)
Development time: 2.30 min
Water rise: 5 min
   Step E: “Plasma Polymerisation Deposition”
   “Substrate Pre-Treatment”

The surface is first treated with argon so as to clean and possibly activate the surface.

The pre-treated 4″ silicon wafers were placed in a 135 litre 2-phase AC-plasma chamber. The pressure in the chamber was lowered to 0.05 mbar and a flow of 20 sccm argon was led into the chamber. Plasma power density of 5 W/litre was started.

Hydrogen is then provided with the aim of reducing any Si—OH groups on the surface to Si—H groups so that the subsequently added p-xylene were able to form Si—C—R bonds with the silicon substrate. Without the reduction with hydrogen, it is believed that base labile Si—O—C—R groups could have been formed.

After 60 seconds, the flow of argon was lowered to 10 sccm and a flow of hydrogen (10 sccm) was started.

After another 30 seconds the argon flow stopped.

“Base Coating by Plasma Polymerisation Deposition of p-xylene on Developed Resist”

After 60 seconds with hydrogen plasma, the hydrogen flow was stopped, a flow of p-xylene vapour (20 sccm) and a flow of argon (10 sccm) were started. The plasma power density was lowered to 3 W/litre.

After 60 seconds with plasma polymerisation of p-xylene, the p-xylene flow was stopped. The plasma was turned off, all flows were stopped and the pressure was raised to atmospheric pressure.

Step F: Lift-Off—Chemical/Mechanical

Solvent: Acetone

Ultrasound is used to promote the lift-off.

In other embodiments the lift-off step include mechanical lift-off, or metal sacrificial layer etching.

This p-xylene base coating provides a hydrophobic functionality to the surface.

### Example 2

### “Lift-Off Microstructuring on Silicon Wafers—Top Coating by Plasma Polymerisation Deposition of 1-vinyl-2-pyrrolidone—Hydrophilic Functionality”

Example 1 was repeated except that Step E was modified to include a top coating by plasma polymerisation deposition of 1-vinyl-2-pyrrolidone as follows:

A flow of 1-vinyl-2-pyrrolidone (15 sccm) was started after the xylene flow was stopped. The power was lowered to 0.5 W/litre and the pressure was raised to 0.1 mbar. The plasma polymerisation of 1-vinyl-2-pyrrolidone was continued for 120 seconds. The plasma was turned off, all flows were stopped and the pressure was raised to atmospheric pressure.

The final layer of poly(vinyl pyrrolidone) provides a hydrophilic functionality; primarily supplied by the pyrrolidone group which requires a low plasma power density to remain intact during the plasma deposition.

### Example 3

### “Lift-Off Microstructuring on Silicon Wafer—Sequential Top Coatings by Plasma Polymerisation Deposition of p-xylene and 1-vinyl-2-pyrrolidone—Hydrophobic and Hydrophilic Functionalities”

The process sequence was performed twice in sequence on the same silicon wafer substrate. A hydrophobic pattern and a hydrophilic pattern were prepared as described in Example 1 and Example 2, respectively.

The procedural steps, repeated twice with alignment there between, are shown in FIG. 5. Letters are “written” with alternating hydrophilic 601 and hydrophobic 602 letters. The letters have a height of 35 μm and a width of 25 μm.

### Example 4

### “Tests of Glass Substrates—Top Coating by Plasma Polymerisation Deposition of p-xylene—Contact Angle and Alkaline Resistance”

Test coatings of plasma polymerised p-xylene on glass, prepared according to example 1, were refluxed in acetone and toluene, respectively, for 24 hours. The contact angle with water was subsequently measured in order to determine whether the coating was left on the substrate. All samples showed a contact angle of between 85° and 95° (water on glass would give a contact angle of approx. 40°). The measured contact angle was substantially equal to the contact angle measured before the refluxing.

Similar samples were tested in alkaline environment in solutions of NaOH. The coatings resisted a solution with pH 12.5 for more than 24 hours and a solution with pH 14 for more than 1 hour. It was therefore concluded that the coating layers were able to resist even harsh conditions as those prevailing in lift-off microstructuring processes.

### Example 5

### “Glass Substrate—Top Coating by Plasma Polymerisation Deposition of diethyleneglycol-vinylether—Cell Non-Adhesive Functionality”

Example 2 was repeated except that glass was used as substrate instead of SiO₂-grown silicon wafer and that diethyleneglycol-vinylether (DEGVE) was used instead of 1-vinyl-2-pyrrolidone. The microstructured surfaces exhibited a contact angle of 10° and cell non-adhesive properties.

### Example 6

### “Lift-Off Microstructuring of Silicon Wafer—Top Coating by Plasma Polymerisation Deposition of Tetra-methylsilane and Trimethylphosphide—Hydrophilic and Cell Non-Adhesive Coating Functionalities”

A silicon wafer (substrate) was placed in a 30-litre cylindrical plasma chamber equipped with a two-phase electrode system—as described above. Tetramethylsilane (TMS) and trimethylphosphide (TMPP) were use as top coating monomers.

The substrate was treated in three steps under the following conditions, respectively:
1) pre-treatment: Ar plasma at pressure 0.1 mbar, Ar flow 8 sccm, AC voltage 250 V, and duration 120 s,
2) base-coating: Ar/H₂ plasma at pressure 0.1 mbar, Ar flow 4 sccm and H₂ flow 5 sccm, AC voltage 250 V, and duration 300 s,
3) top-coating: Ar/TMS/TMPP/air plasma at pressure 0.1 mbar, Ar flow 4 sccm, TMS flow 5 sccm, TMPP flow 5 sccm, and air flow 3 sccm, AC voltage 250V, and duration 300 s.

An IR spectrum of the coating on the NaCl crystal was recorded, showing absorption bands at 961 cm⁻¹ (P—O, Si—O or Si—H) and 1070 cm⁻¹ (Si—O), 1165 cm⁻¹ (P═O), 1445 cm⁻¹ (CH₂), 1647 cm⁻¹ (C═C and P—OH), 2855 cm⁻¹ (CH₂), 3200 cm⁻¹ (OH), 3400 cm⁻¹ (OH).

The static contact angle of demineralized water with the coated silicon wafer was measured to be 18.6 degrees with a standard deviation of 2.2.

“Test of Cell Adhesive Functionality”

Cell adhesive and/or non-adhesive properties of plasma polymerised surfaces were tested by bacterial sedimenttation thereon.

Two square pieces, samples, of approximately 1 cm² were cut from the wafer and tested independently in the following way:

The surface of the sample was exposed to a bacterial culture (E. Coli k-12) which previously had been washed with ice-cold water and resuspended into ice-cold phosphate buffer saline (PBS). The bacteria suspension was allowed to sediment onto the surface for one hour before a gentle flow (1 ml/min) of PBS was induced over the surface to remove unattached bacteria.

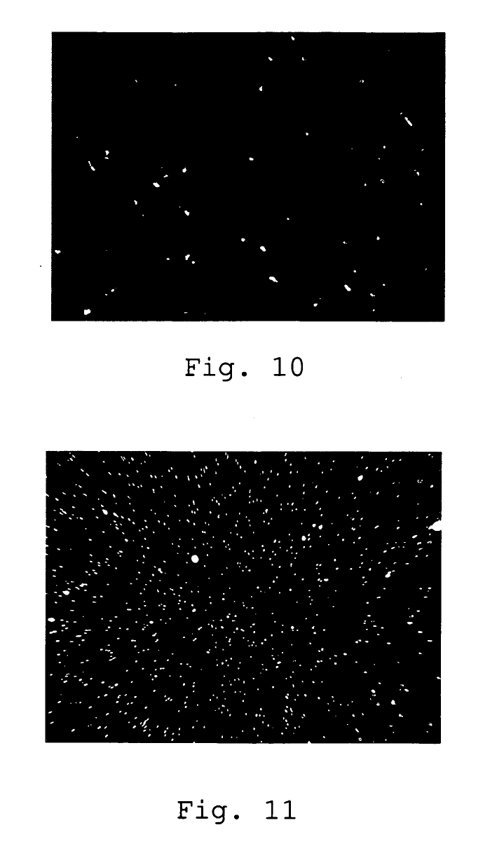

Finally the samples were investigated with a microscope using an objective with 10 times magnification. Images were recorded with the use of a CCD camera. The images are shown in FIG. 8 and FIG. 9 (width 0.7 mm, height 0.5 mm).

FIG. 8 shows a sample for which no cell sedimentation can be observed whereas FIG. 9 shows a sample for which single cells sediments (bright spots) are scattered across the surface.

In conclusion, a silicon wafer with a hydrophilic and cell non-adhesive coating was successfully produced.

### Example 7

### “Silicon Wafer—Top Coating by Plasma Polymerisation Deposition of Difluoroethylene—Hydrophobic and Cell Adhesive Functionalities”

A highly fluorinated polymer is generally known to have hydrophobic properties. In this example, a hydrocarbon base coating was deposited on a silicon wafer (substrate) by plasma polymerisation of hexene as monomer. On this base coating a fluorinated top coating was deposited by plasma polymerisation of difluoroethylene as monomer.

The substrate was placed in the plasma chamber described in the above example.

As an initiation step, a flow of 2.5 sccm Ar was established and the plasma was ignited at 1200 V. After 1 minute, 20 sccm hexene was added to the gas flow and the voltage was lowered to 1000 V. At these conditions the plasma was maintained for 1 minute. The hexene flow was then stopped, and a difluoroethylene flow of 38.4 sccm was started. After ten minutes the plasma was ignited at 700 V and the top coating was deposited with a flow of 2.5 sccm Ar and 38.4 sccm difluoroethylene for 2 minutes.

The static contact angle with demineralised water was measured to be 67.4 degrees, with a 0.9 standard deviation.

The FT-IR spectrum was recorded of the top coating, showing absorption bands at 881 cm⁻¹ (Si—F), 1350-1120 cm⁻¹ (C—F), 1440 cm⁻¹ (CH₂), 1650-1700 cm⁻¹ (C═C or C—F), 2957 cm⁻¹ (CH₂).

The cell adhesive properties were tested by the test of cell adhesive functionality. The results for the two samples are shown in FIG. 10 and FIG. 11, respectively. The number of cells per area is clearly higher for this surface than for the surface described in example 6.

In conclusion a silicon wafer could successfully be provided a hydrophobic functionality and a moderately cell adhesive functionality.

### Example 8

### “Glass Slides—Top Coating by Plasma Polymerisation Deposition of Carboxylic Acid Anhydride”

Substrates, here 10 microscope glass slides pre-treated according to the substrate pre-treatment procedure described above, of length 7.62 cm (3 inch), width 2.53 cm (1 inch), and thickness 1 mm, were placed in a substrate holder which was then placed a 300 litres cylindrical plasma chamber equipped with a two-phase electrode system (135 litres).

In this embodiment, substrates were treated on one side only by covering the other sides with a cover substrate; here a microscope glass slides similar to the deposition substrate. Each substrate was placed on a supporting slide of same dimensions before being placed in the chamber.

The 10 pairs of supports and substrates were evenly distributed on a substrate holder, here a tray, comprising a stainless steel grid electrically isolated from the electrodes.

A rectangular calibration NaCl crystal was placed on a supporting slide in the middle of the chamber.

The glass slides, and the calibration crystal, were subjected to three consecutive gas treatments providing a polystyrene base coating:
Ar-plasma pre-treatment: exposure to an Ar-plasma at pressure 0.025 mbar, said plasma being provided by an argon flow of 25 sccm, a plasma power density of 3 Watt/litre, and had a duration of 60 s.
Ar/H₂-plasma pre-treatment: exposure to an Ar/H₂-plasma at pressure 0.025 mbar, said plasma being provided by an argon flow of 17 sccm, H₂-flow of 7 sccm, a plasma power density 3 Watt/litre, and had a duration of 60 s,
polystyrene base coating: exposure to a styrene/Ar-plasma at a pressure of 0.075 mbar, said base coating plasma being provided by a styrene flow of 80 sccm, an argon flow of 40 sccm, and a plasma power density of 2 Watt/litre, and had a duration of 120 seconds.

The FT-IR spectrum was recorded of the base coating, showing absorption bands at 3056 and 3025 cm⁻¹ (aromatic C—H), 2800-2900 cm⁻¹ (—CH₂—, —CH₃), 1601 cm⁻¹ (aromatic C—C) 1451 cm⁻¹ (—CH₂—), 1373 cm⁻¹ (—CH₃).

Ten pressure-sensitive tape masks were prepared: A pressure sensitive adhesive tape (PSA) was prepared by evenly spreading 20 ml of a solution consisting of 18 g of thermoplastic elastomer, Kraton KX601 supplied by Shell Chemicals, and 5 grams of tackifying resin, Arkon P15 supplied by Arkava, dissolved in 250 ml of xylene, over a piece of thin writing paper (30 cm long and 21 cm wide) and letting the xylene evaporate. From the resulting PSA sheet 10 rectangular pieces of microscope slide format were punched. The punch was designed such that 24 holes of diameter 3 mm were produced in the paper. The holes were arranged in 3 rows of 8 circular holes, neighbouring holes being 3 mm apart.

Each of the polystyrene base coated slides were covered on one side by one such PSA mask and transferred to the plasma chamber together with the calibration crystal.

A methacrylic acid anhydride (MAAH) top coating was deposited by exposure to a plasma at a pressure of 0.3 mbar, said top-coating plasma being provided by bobbling argon through liquid MAAH at a flow of 5 sccm and feeding the MAAH/Ar-gas mixture to the plasma chamber, a plasma power density of 1.5 Watt/litre, and had a duration of 300 s. After the plasma treatment the PSA masks were removed by hand.

Characterisation of the Product:

A plasma treated slide was briefly submerged in demineralised water and then kept in a vertical position. Water was observed to de-wett in areas of the slide covered by the mask, whereas water remained in the circular spots generated by exposure to the MAAH/Ar-plasma.

The chemical structure of the coating was analysed by infrared spectroscopy of the coated NaCl-calibration crystal.

Additional FT-IR absorption peaks were observed at 3100-3600 cm⁻¹ (O—H), 1772-1800 cm⁻¹ (acid anhydride C═O), 1130 cm⁻¹ (acid anhydride C-0).

In result, a chemically structured surface was produced with well-defined hydrophilic spots in a hydrophobic matrix.

### Example 10

### “Plasma Polymerisation Deposition Of Allylamine”

A silicon wafer, substrate, was placed on a tray in a plasma apparatus. The apparatus comprising a 30 litres cylindrical plasma chamber equipped with a two-phase cylindrical electrode system of volume 3 litres.

The electrodes were connected to a two-phase 50 Hz AC-power supply with a manually tuneable voltage. A rectangular NaCl crystal was placed next to the substrate on the tray.

The substrate, and the NaCl crystal, was subjected to three consecutive gas treatments providing a base coating and a top coating:
the pre-treatment: exposure to an Ar-plasma at a pressure of 0.07 mbar, said plasma being provided by an argon flow of 25 sccm, and an AC voltage 1200 V of 50 cycles per second, and had a duration of 60 s, and
the base coating: exposure to a hexene/Ar-plasma at a pressure 0.1 mbar, said top-coating plasma being provided by an hexene flow of 20 sccm, an Ar-flow of 2.5 sccm, and an AC voltage of 1000 V of 50 cycles per second, and had duration 60 s.
the top coating: exposure to an allylamine/Ar-plasma at a pressure 0.2 mbar, said top-coating plasma being provided by an allylamine flow of 30 sccm, an Ar-flow of 2.5 sccm, and an AC voltage of 700 V of 50 cycles per second, and had a duration 120 s.

Placing a droplet of demineralised water on a substrate coated as described above and observing the contact angle with water tested the affinity of the coating towards water. Typical contact angles were about 50 degrees.

The chemical structure of the coating was analysed by infrared spectroscopy of the coated NaCl-calibration crystal.

The following absorption peaks were observed: 3370 cm⁻¹ (primary amine), 2800-2900 cm⁻¹ (—CH₂—, —CH₃), 2206 cm⁻¹ (nitrile), 1629 cm⁻¹ (primary amine), 1452 cm⁻¹ (—CH₂—), 1375 cm⁻¹ (—CH₃).

In conclusion a silicon wafer with a hydrophilic amine rich coating was produced.

1-41. (canceled)

42. A process of lift-off microstructuring of a polymer on a substrate, said process comprising the steps of:
(a) providing the substrate having a sacrificial layer in a predetermined micro-pattern;
(b) depositing a polymer layer on the sacrificial layer/substrate; and
(c) dissolving/etching the underlying sacrificial layer (lift-off),
characterized in that the polymer layer is constituted by a cross-linked polymeric material prepared by plasma polymerization of a monomer gas in a plasma, said monomer gas comprising one or more types of substituted benzenes.

43. The process according to claim 42 wherein the polymer layer is functionalised prior to dissolution of the underlying layer.

44. The process according to claim 42 said process comprising the steps of:
(a) spinning a UV-sensitive photoresist on the substrate;
(b) masking the resist with a predetermined pattern and exposing the resist to UV light through the mask;
(c) developing the resist;
(d) depositing a polymer layer on the resist/substrate; and
(e) dissolving the underlying UV-sensitive photoresist (lift-off).

45. A process according to claim 42 wherein the one or more types of monomers are selected from substituted benzenes.

46. The process according to claim 45 wherein the substituted benzene has the general formula:
Ar(Rⁿ)ₙ
wherein Ar is a benzene ring, n is 1-6, and Rⁿ is n substituents (R¹, R², R³, R⁴, R⁵, R⁶) covalently bound to the benzene ring, the substituents (R¹, R², R³, R⁴, R⁵, R⁶) being independently selected from C₁₋₆-alkyl, C₁₋₆-alkenyl, C₁₋₆-alkynyl, C₁₋₆-alkoxy, C₁₋₆-alkylcarbonyl, C₁₋₆-alkylcarbonyl, C₁₋₆-alkoxycarbonyl, carbamoyl, mono- and di(C₁₋₆-alkyl)aminocarbonyl, formyl, hydroxy, carboxy, carbamido, thiolo, nitro, cyano, nitro, amino, mono- and di(C₁₋₆-alkyl)amino, and halogen (fluoro, chloro, iodo, bromo), wherein the C₁₋₆-alkyl, C₁₋₆-alkenyl, C₁₋₆-alkynyl and C₁₋₆-alkoxy groups in the above may be substituted with substituents selected from hydroxy, C₁₋₆-alkoxy, carboxy, amino, mono- and di(C₁₋₆-alkyl)amino and halogen.

47. The process according to claim 45 wherein less than 10% of the double bonds originating from the substituted benzene are left in the material.

48. A process according to claim 42 wherein the substituted benzene monomer or monomers constitute(s) at least 5% of the monomer gas.

49. A process according to claim 42 wherein said a sacrificial layer (302) on the substrate (301) comprises a mask with a complementary pattern of holes, said pattern corresponding to that of the microstructure to be deposited on the substrate, said holes being adapted to expose corresponding parts of the substrate and adapted to receive deposition material.

50. A process according to claim 42 wherein the process steps are repeated two or more times.

51. A substrate prepared according to the process defined in claim 42.

52. A device comprising a micro-patterned structure said device comprising a substrate and a plurality of patches and/or areas comprising a cross-linked material prepared according to the process defined in claim 42.

53. The device according to claim 52 wherein the plurality of patches comprising the cross-linked material represent any of the following combinations of surface properties:
(i) a subset of the patches and/or areas having a cell-adhesive surface and a subset of the patches and/or areas having a hydrophobic surface;
(ii) a subset of the patches and/or areas having a cell non-adhesive surface and a subset of the patches and/or areas having a hydrophobic surface;
(iii) a subset of the patches and/or areas having a cell-adhesive surface and a subset of the patches and/or areas having a hydrophilic surface; or
(iv) a subset of the patches and/or areas having a cell-non-adhesive surface and a subset of the patches and/or areas having a hydrophilic surface.

54. A process of lift-off microstructuring of a polymer on a substrate, said process comprising the steps of:
(a) providing the substrate having a sacrificial layer in a predetermined micro-pattern;
(b) depositing a polymer layer on the sacrificial layer/substrate; and
(c) dissolving/etching the underlying sacrificial layer (lift-off),
characterised in that the polymer layer is constituted by a cross-linked polymeric material prepared by plasma polymerisation of a monomer gas in a plasma, said monomer gas comprising one or more types of (halo)aliphatic compounds of the general formula C_{z}H_{y}Xₓ wherein X is fluoro, chloro, bromo or iodo, z is 1-16 and x+y is 2z+2, 2z, 2z-2 or 2z-4;
with the proviso that said (halo)aliphatic compounds are not CF₄, C₂F₆, or C₃F₈ when said monomer gas is a gas mixture with H₂; and not CHF₃.

55. The process according to claim 54 wherein the polymer layer is functionalised prior to dissolution of the underlying layer.

56. The process according to claim 54 said process comprising the steps of:
(a) spinning a UV-sensitive photoresist on the substrate;
(b) masking the resist with a predetermined pattern and exposing the resist to UV light through the mask;
(c) developing the resist;
(d) depositing a polymer layer on the resist/substrate; and
(e) dissolving the underlying UV-sensitive photoresist (lift-off).

57. A process according to claim 54 wherein said a sacrificial layer (302) on the substrate (301) comprises a mask with a complementary pattern of holes, said pattern corresponding to that of the microstructure to be deposited on the substrate, said holes being adapted to expose corresponding parts of the substrate and adapted to receive deposition material.

58. A process according to claim 54 wherein the process steps are repeated two or more times.

59. A substrate prepared according to the process defined in claim 54.

60. A device comprising a micro-patterned structure said device comprising a substrate and a plurality of patches and/or areas comprising a cross-linked material prepared according to the process defined in claim 54.

61. The device according to claim 60 wherein the plurality of patches comprising the cross-linked material represent any of the following combinations of surface properties:
(i) a subset of the patches and/or areas having a cell-adhesive surface and a subset of the patches and/or areas having a hydrophobic surface;
(ii) a subset of the patches and/or areas having a cell non-adhesive surface and a subset of the patches and/or areas having a hydrophobic surface;
(iii) a subset of the patches and/or areas having a cell-adhesive surface and a subset of the patches and/or areas having a hydrophilic surface; or
(iv) a subset of the patches and/or areas having a cell-non-adhesive surface and a subset of the patches and/or areas having a hydrophilic surface.

62. A method of lift-off microstructuring of a polymer on a substrate, said process comprising the steps of:
(a) providing the substrate having a sacrificial layer in a predetermined micro-pattern;
(b) depositing a polymer layer on the sacrificial layer/substrate; and
(c) dissolving/etching the underlying sacrificial layer (lift-off),
characterised in that the polymer layer is constituted by a cross-linked polymeric material prepared by plasma polymerisation of a monomer gas in a plasma, said monomer gas comprising one or more types of monomers selected from: vinyls, substituted vinyls, acrylics, silanes, and phosphites, or a combination thereof.

63. The method according to claim 62 wherein said acrylic monomer is selected from: acrylic acid, methylmethacrylate, acrolein, acryloylchloride, acrylonitrile.

64. The method according to claim 62 wherein said vinylic monomer is selected from: ethylene, propylene, styrene, N-vinylpyrrolidone.

65. The method according to claim 62 wherein said substituted vinylic monomer is selected from: vinyl-di-fluoride, hexafluoropropane, vinylchloride.

66. The method according to claim 62 wherein said silane monomer is selected from: tetramethylsilane, hexamethyl-di-silane, tri-methylchlorosilane.

67. The method according to claim 62 wherein said silane tri-phosphite is selected from: tri-methyl-phosphite, tri-ethyl-phosphite.

68. A method according to claim 62 wherein the polymer layer is functionalised prior to dissolution of the underlying layer.

69. A method according to claim 62 wherein said process comprising the steps of:
(a) spinning a UV-sensitive photoresist on the substrate;
(b) masking the resist with a predetermined pattern and exposing the resist to UV light through the mask
(c) developing the resist;
(d) depositing a polymer layer on the resist/substrate; and
(e) dissolving the underlying UV-sensitive photoresist (lift-off).

70. A method according to claim 62 wherein said a sacrificial layer (302) on the substrate (301) comprises a mask with a complementary pattern of holes, said pattern corresponding to that of the microstructure to be deposited on the substrate, said holes being adapted to expose corresponding parts of the substrate and adapted to receive deposition material.

71. A method according to claim 62 wherein the process steps are repeated two or more times.

72. A substrate prepared according to the method defined in claim 62.

73. A device comprising a micro-patterned structure said device comprising a substrate and a plurality of patches and/or areas comprising a cross-linked material prepared according to the method defined in claim 62.

74. The device according to claim 73 wherein the plurality of patches comprising the cross-linked material represent any of the following combinations of surface properties:
(i) a subset of the patches and/or areas having a cell-adhesive surface and a subset of the patches and/or areas having a hydrophobic surface;
(ii) a subset of the patches and/or areas having a cell non-adhesive surface and a subset of the patches and/or areas having a hydrophobic surface;
(iii) a subset of the patches and/or areas having a cell-adhesive surface and a subset of the patches and/or areas having a hydrophilic surface; or
(iv) a subset of the patches and/or areas having a cell-non-adhesive surface and a subset of the patches and/or areas having a hydrophilic surface.

75. A method of lift-off micro-structuring a deposition of material on a substrate, the method comprising:
(a) providing the substrate (401), the substrate comprising a sacrificial layer (402) thereon, said sacrificial layer having a predetermined micro-pattern;
(b) depositing the deposition material (405) on the substrate and said sacrificial layer; and
(c) dissolving/etching said sacrificial layer,
wherein said deposition material is a polymer, said polymer comprising a cross-linked polymeric material prepared by plasma polymerisation of a monomer gas in a plasma, said plasma being generated by a multiple phase AC supply (708,709,710), or a DC supply.

76. The method according to claim 75 wherein said multiple phase AC supply is two-phase or three-phase AC supply.

77. The method according to claim 75 wherein said multiple two or three phase AC supply generates plasma having plasma power density up to 15 W/l.

78. The method according to claim 75 wherein said multiple two or three phase AC supply generates plasma having plasma power density in the range 0.010 to 10 W/l.

79. The method according to claim 75 wherein said multiple two or three phase AC supply generates plasma having plasma power density in the range 0.010 to 5 W/l.

80. A method according to claim 75 wherein said plasma is provided in a reaction chamber having a pressure in the range 10-1000 μbar.

81. A method according to claim 75 wherein said plasma is provided in a reaction chamber having a pressure in the range 25-500 μbar.

82. A method according to claim 75 wherein said monomer gas comprises one or more types of monomers, and a supply of inert gas.

83. A method according to claim 75 wherein said monomer gas comprises one or more types of monomers selected from:
(i) substituted benzenes, and
(ii) (halo)aliphatic compounds of the general formula C_{z}H_{y}Xₓ wherein X is fluoro, chloro, bromo or iodo, z is 1-16 and x+y is 2z+2, 2z, 2z-2 or 2z-4; or
(iii) a combination there of.

84. A method according to claim 75 wherein said monomer gas comprises one or more types of monomers selected from: vinyls, substituted vinyls, acrylics, silanes, and phosphites, or a combination thereof.

85. The method according to claim 84 wherein said acrylic monomer is selected from: acrylic acid, methylmethacrylate, acrolein, acryloylchloride, acrylonitrile.

86. The method according to claim 84 wherein said vinylic monomer is selected from: ethylene, propylene, styrene, N-vinylpyrrolidone.

87. The method according to claim 84 wherein said substituted vinylic monomer is selected from: vinyl-di-fluoride, hexafluoropropane, vinylchloride.

88. The method according to claim 84 wherein said silane monomer is selected from: tetramethylsilane, hexamethyl-di-silane, tri-methylchlorosilane.

89. The method according to claim 84 wherein said silane tri-phosphite is selected from: tri-methyl-phosphite, tri-ethyl-phosphite.

90. A method according to claim 75 wherein the method steps are repeated two or more times.

91. A substrate prepared according to the method defined in claim 75.

92. A device comprising a micro-patterned structure said device comprising a substrate and a plurality of patches and/or areas comprising a cross-linked material prepared according to the method defined in claim 75.

93. The device according to claim 92 wherein the plurality of patches comprising the cross-linked material represent any of the following combinations of surface properties:
(i) a subset of the patches and/or areas having a cell-adhesive surface and a subset of the patches and/or areas having a hydrophobic surface;
(ii) a subset of the patches and/or areas having a cell non-adhesive surface and a subset of the patches and/or areas having a hydrophobic surface;
(iii) a subset of the patches and/or areas having a cell-adhesive surface and a subset of the patches and/or areas having a hydrophilic surface; or
(iv) a subset of the patches and/or areas having a cell-non-adhesive surface and a subset of the patches and/or areas having a hydrophilic surface.
